(19) United States
(12) Patent Application Publication
(10) Pub. No.: US 2022/0002860 A1
(43) Pub. Date: Jan. 6, 2022

(54) MASK ASSEMBLY AND DEPOSITION APPARATUS INCLUDING THE SAME

(71) Applicant: Samsung Display Co., Ltd., Yongin-si (KR)

(72) Inventor: Young Kwang Lee, Incheon (KR)

(21) Appl. No.: 17/226,578

(22) Filed: Apr. 9, 2021

(30) Foreign Application Priority Data
Jul. 3, 2020 (KR) 10-2020-0082090

(51) Int. Cl. C23C 14/04; C23C 14/24

(52) U.S. Cl. CPC C23C 14/042; H01L 51/0011; C23C 14/24

(57) ABSTRACT

A mask assembly and a deposition apparatus including the same are provided. A mask assembly includes: a frame in which a frame opening is defined; a plurality of support sticks coupled with the frame to overlap the frame opening, each of the plurality of support sticks extending in a first direction, and the support sticks being arranged in a second direction crossing the first direction; and a mask on the frame and the support sticks, and extending in the second direction, and the support sticks have a magnetic moment of about 10 emu/g or more and about 100 emu/g or less.

### CROSS-REFERENCE TO RELATED APPLICATION

This application claims priority to and the benefit of Korean Patent Application No. 10-2020-0082090, filed on Jul. 3, 2020 in the Korean Intellectual Property Office, the entire content of which is hereby incorporated by reference.

### BACKGROUND

### 1. Field

Aspects of embodiments of the present disclosure relate to a mask assembly and a deposition apparatus including the same.

### 2. Description of the Related Art

In general, a light emitting display device includes a light emitting device disposed at each pixel. The light emitting device includes a light emitting layer disposed between spaced electrodes. The light emitting layers contained in the pixels may be distinguished into a plurality of groups.

Here, a mask assembly is used to deposit the plurality of groups of light emitting layers to a working substrate. The mask assembly includes a frame, a support stick, and a mask. As the working substrate is disposed on the mask, and then a light emitting material is deposited to the working substrate, patterned light emitting layers may be provided.

### SUMMARY

According to aspects of embodiments of the present disclosure, a mask assembly capable of preventing or substantially preventing deformation thereof and a deposition apparatus including the same are provided. According to an aspect, a mask assembly is hardly deformed. Thus, the present disclosure provides a deposition apparatus having improved reliability.

According to one or more embodiments, a mask assembly includes: a frame in which a frame opening is defined; a plurality of support sticks coupled with the frame to overlap the frame opening, each of the plurality of support sticks extending in a first direction, and the support sticks being arranged in a second direction crossing the first direction; and a mask on the frame and the support sticks, and extending in the second direction, and the support sticks have a magnetic moment of about 10 emu/g or more and about 100 emu/g or less.

In an embodiment, the mask may have a magnetic moment greater than that of the support sticks.

In an embodiment, each of the support sticks may have a thickness of about 20 μm or more and about 200 μm or less.

In an embodiment, each of the support sticks may include stainless steel, and the mask may include nickel or nickel alloy.

In an embodiment, the mask may include a plurality of deposition holes, a portion of the plurality of deposition holes may be covered by the support sticks, and remaining ones of the plurality of deposition holes may be exposed by the support sticks.

In an embodiment, the frame may include: a first extension portion and a second extension portion, which face each other in the first direction; and a third extension portion and a fourth extension portion, which face each other in the second direction and each connect the first extension portion and the second extension portion.

In an embodiment, a first end of each of the support sticks may be welded to the first extension portion, and a second end of each of the support sticks may be welded to the second extension portion, such that the support sticks may be coupled to the frame.

According to one or more embodiments, a deposition apparatus includes: a chamber; a deposition source in the chamber; a mask assembly above the deposition source and configured to support a base substrate thereon; and a pressing part including a support plate above the base substrate, and a magnetic plate having a magnetic force, and the mask assembly includes: a frame in which a frame opening configured to expose at least a portion of the base substrate is defined; a plurality of support sticks coupled with the frame to overlap the frame opening; a mask on the frame and the support sticks and in which a plurality of deposition holes is defined, and the support sticks have a magnetic moment of about 10 emu/g or more and about 100 emu/g or less.

In an embodiment, each of the support sticks may have a thickness of about 20 μm or more and about 200 μm or less.

In an embodiment, a magnetic force between the magnetic plate and the mask may be greater than that between the magnetic plate and the support sticks.

In an embodiment, the mask may have a magnetic moment greater than that of the support sticks.

In an embodiment, each of the support sticks may include stainless steel, and the mask may include nickel or nickel alloy.

In an embodiment, the deposition source may include an organic material and be configured to evaporate the organic material to inject the evaporated organic material to the frame opening.

In an embodiment, the deposition apparatus may further include a seating part configured to support the mask assembly.

In an embodiment, the deposition apparatus may further include a transferring part including: a transferring rod connected with the pressing part and located in the chamber; and a transferring main body connected with the transferring rod to control the transferring rod and located outside the chamber.

In an embodiment, a tensile force applied to the support sticks when the pressing part contacts the base substrate by the transferring part may be about 0 (zero).

In an embodiment, the base substrate may include: a base layer; a circuit device layer on the base layer and including a transistor including a plurality of electrodes; a pixel defining layer on the circuit device layer and in which a plurality of display openings are defined; first electrodes in which at least one portion is exposed by the display openings; and a hole control layer on the pixel defining layer, and at least a portion of the plurality of deposition holes may overlap the display openings.

In an embodiment, a portion of the plurality of deposition holes may be covered by the support sticks, and remaining ones of the plurality of the deposition holes may be exposed by the support sticks.

In an embodiment, the frame may include: a first extension portion and a second extension portion, which face each other in a first direction; and a third extension portion and a fourth extension portion, which face each other in a second direction crossing the first direction and each connect the first extension portion and the second extension portion.

In an embodiment, a first end of each of the support sticks may be welded to the first extension portion, and a second end of each of the support sticks may be welded to the second extension portion, such that the support sticks may be coupled to the frame.

### BRIEF DESCRIPTION OF THE DRAWINGS

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a view illustrating a deposition apparatus according to an embodiment of the inventive concept;

FIG. 2 is an exploded perspective view illustrating components of a deposition apparatus according to an embodiment of the inventive concept;

FIG. 3 is a plan view illustrating a portion of a support stick and a mask according to an embodiment of the inventive concept;

FIG. 4 is a cross-sectional view illustrating components of a deposition apparatus according to an embodiment of the inventive concept;

FIG. 5 is a cross-sectional view illustrating a display panel according to an embodiment of the inventive concept;

FIG. 6 is an enlarged plan view illustrating a region “VA” of FIG. 2;

FIG. 7A is an enlarged plan view illustrating a first mask according to an embodiment of the inventive concept;

FIG. 7B is a cross-sectional view illustrating an arrangement relationship between the first mask in FIG. 7A and a unit cell area;

FIG. 8 is an enlarged plan view illustrating a second mask according to an embodiment of the inventive concept; and

FIG. 9 is an enlarged plan view illustrating a third mask according to an embodiment of the inventive concept.

### DETAILED DESCRIPTION

It is to be understood that when an element, such as a region, layer, or portion is referred to as being “on” another element, it may be directly on the other element or one or more intervening elements may also be present.

Like reference numerals refer to like elements throughout. Also, in the figures, the thickness, ratio, and dimensions of components may be exaggerated for clarity of illustration.

The term “and/or” includes any and all combinations of one or more of the associated listed items.

It is to be understood that although terms such as “first” and “second” are used herein to describe various elements, these elements are not to be limited by these terms. These terms are used to distinguish one component from other components. For example, a first element referred to as a first element in one embodiment can be referred to as a second element in another embodiment without departing from the scope of the appended claims. The terms of a singular form may include plural forms unless referred to the contrary.

Also, “under,” “below,” “above,” “upper,” and the like may be used for explaining relation association of components illustrated in the drawings. The terms may be a relative concept and described based on directions expressed in the drawings.

Unless otherwise defined, all terms (including technical and scientific terms) used herein have the same meaning as generally understood by those skilled in the art. Terms as defined in a commonly used dictionary should be construed as having the same meaning as in an associated technical context, and unless defined in the description, the terms are not to be ideally or excessively construed as having formal meaning.

The meaning of “include” or “comprise” specifies a property, a fixed number, a step, an operation, an element, a component, or a combination thereof, but does not exclude other properties, fixed numbers, steps, operations, elements, components, or combinations thereof. Herein, embodiments of the inventive concept will be described with reference to the accompanying drawings.

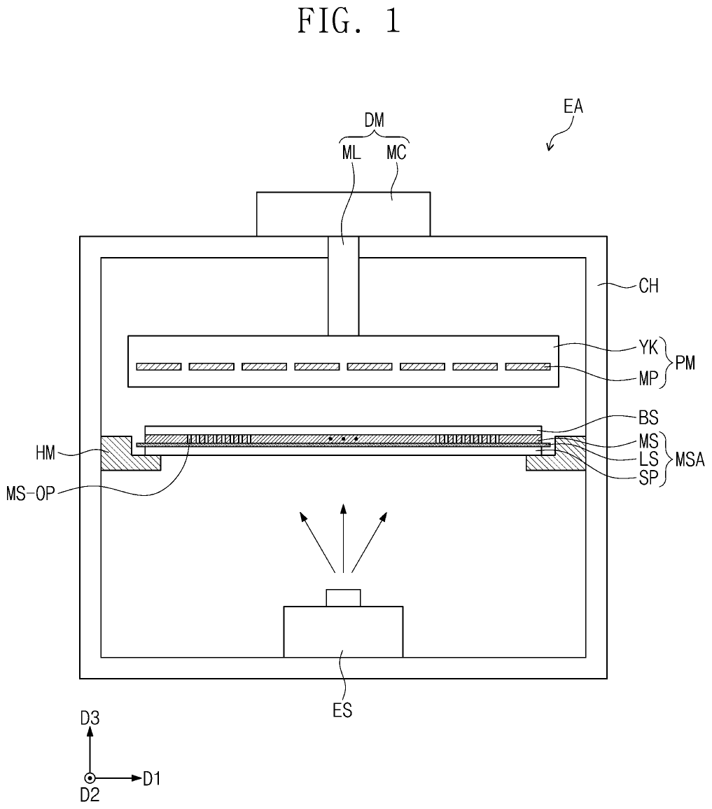

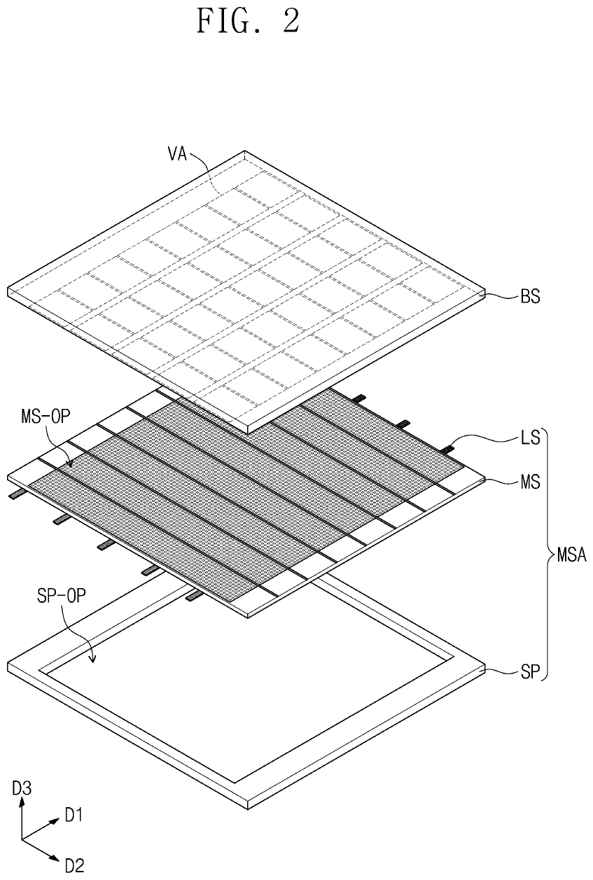

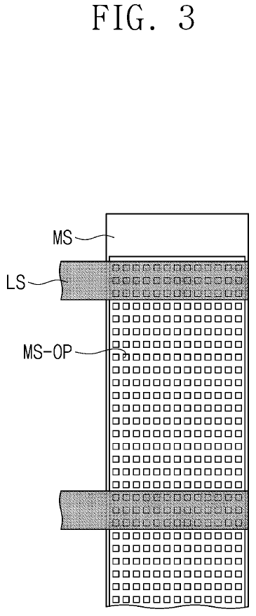

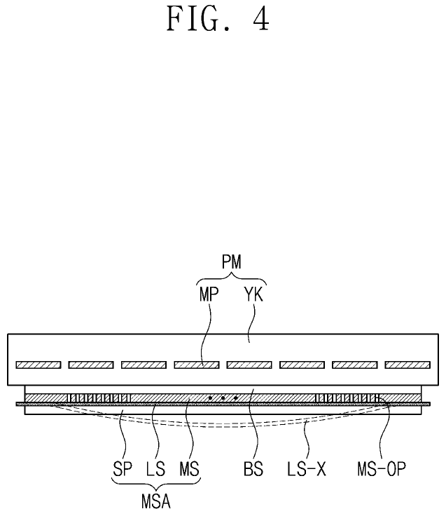

FIG. 1 is a view illustrating a deposition apparatus according to an embodiment of the inventive concept; FIG. 2 is an exploded perspective view illustrating components of a deposition apparatus according to an embodiment of the inventive concept; FIG. 3 is a plan view illustrating a portion of a support stick and a mask according to an embodiment of the inventive concept; and FIG. 4 is a cross-sectional view illustrating components of a deposition apparatus according to an embodiment of the inventive concept.

A deposition apparatus EA according to an embodiment of the inventive concept includes a chamber CH, a deposition source ES, a seating part HM, a mask assembly MSA, a pressing part PM, and a transferring part DM, and the deposition apparatus EA may deposit an organic material or a conductive material on a base substrate BS.

The chamber CH provides an inner space in which a deposition process may be performed. The deposition source ES, the seating part HM, the mask assembly MSA, the base substrate BS, the pressing part PM, and a transferring rod ML of the transferring part DM may be disposed in the inner space of the chamber CH.

The deposition source ES provides a deposition material to the base substrate BS. For example, the deposition source ES may evaporate a deposition material (e.g., a predetermined deposition material), such as an organic material or a conductive material toward the mask assembly MSA. Here, the deposition material may pass through the mask assembly MSA and be deposited to the base substrate BS. In an embodiment, this may be implemented in a method in which the deposition source ES heats the deposition material at a high temperature to be evaporated.

In an embodiment, although not shown, the deposition apparatus EA may further include a transferring unit for transferring the deposition source ES in a horizontal direction D1 and D2.

The seating part HM may be disposed on a sidewall of the chamber CH to support the mask assembly MSA. However, embodiments of the inventive concept are not limited to the shape, position, and number of the seating part HM as long as the seating part HM supports the mask assembly MSA.

The mask assembly MSA may be supported by the seating part HM. The mask assembly MSA may include a mask MS, a support stick LS, and a frame SP.

The frame SP may be supported by the seating part HM and disposed on the seating part HM. In the frame SP, an opening (e.g., a predetermined opening) SP-OP exposing deposition holes MS-OP defined in the mask MS may be defined. A plurality of masks may be attached to the frame SP. For example, the plurality of masks arranged in a first direction D1 and each extending in a second direction D2 may be welded and attached to the frame SP.

The frame SP may be made of metal. For example, the frame SP may include a material having a small thermal deformation when welded to be easily coupled with the mask MS.

The support sticks LS may be disposed between the frame SP and the mask MS. A first end and a second end, which is opposite the first end, of each of the support sticks LS may be coupled to the frame SP. Thus, the support sticks LS may be coupled with the frame SP to overlap the frame opening SP-OP. In an embodiment, the first end and the second end, which is opposite the first end, of each of the support sticks LS may be welded and attached to the frame SP.

The support sticks LS may be disposed between the frame SP and the mask MS, which extends in the second direction D2, to prevent or substantially prevent the mask MS from being deflected by gravity. Thus, referring to FIG. 3, a portion of the deposition holes MS-OP of the mask MS may be a non-deposition area that is covered by the support sticks LS to block the deposition material provided from the deposition source ES from being deposited to the base substrate BS, and remaining ones of the deposition holes MS-OP may be a deposition area that are exposed by the support sticks LS and allow the deposition material provided from the deposition source ES to be deposited to the base substrate BS.

The mask MS may be supported by the support stick LS and attached to the frame SP. The mask MS may include the deposition holes MS-OP passing through the mask MS in a third direction D3. The deposition material provided from the deposition source ES may be provided onto a surface of the base substrate BS through the deposition holes MS-OP.

The mask MS may extend in the second direction D2. In an embodiment, a plurality of masks MS may be provided and arranged in the first direction D1. The mask MS may include a metal. For example, the mask MS may include nickel or nickel alloy. Thus, the mask MS may be coupled to a material having a magnetic force. The mask MS according to an embodiment of the inventive concept may be a fine metal mask (FMM).

The frame SP according to an embodiment of the inventive concept may include a first extension portion and a second extension portion, which face each other in the first direction D1, and further include a third extension portion and a fourth extension portion, which face each other in the second direction D2 and extend from the first extension portion and the second extension portion.

In an embodiment, the first end and the second end of each of the support sticks LS may be welded and coupled to the third extension portion and the fourth extension portion, respectively, and a first end and a second end of the mask MS may be welded and coupled to the first extension portion and the second extension portion, respectively. In an embodiment, the support sticks LS may each extend in the first direction D1 and be arranged in the second direction D2.

In an embodiment, both ends of each of the support sticks LS may protrude from the third and fourth connection portions of the frame SP, and the protruding portions may be used to pull and fix both ends by using a clamp (not shown) in a process of fixing the support sticks LS to the frame SP and may then be removed.

In an embodiment, the base substrate BS may be a mother substrate that is an object to be deposited. The base substrate BS may include deposition areas VA. A plurality of deposition areas VA may be arranged in a matrix form along the first direction D1 and the second direction D2. The plurality of deposition areas VA may be defined as an area to which the deposition material provided from the deposition source ES is deposited through the deposition holes MS-OP exposed by the support sticks LS. In an embodiment, each of the plurality of deposition areas VA may be cut into an individual cell unit in a following process.

The pressing part PM may include a magnetic plate MP and a support plate YK. In an embodiment, although not shown, the pressing part PM may further include a cooling plate disposed between the base substrate BS and the support plate YK.

In an embodiment, the magnetic plate MP may be disposed inside the support plate YK. However, embodiments of the inventive concept are not limited to the position, shape, and number of the magnetic plate MP as long as the magnetic plate MP is disposed on the mask MS to couple the mask and the base substrate BS by using a magnetic force.

The magnetic plate MP provides a magnetic force in a state in which the base substrate BS closely contacts the mask MS and pulls the mask MS containing metal by using an attractive force. Thus, a coupling force between the base substrate BS and the mask MS may be increased.

The magnetic plate MP may prevent or substantially prevent a lifting phenomenon generated due to a difference between curvatures of the base substrate BS and the mask MS and thus prevent or substantially prevent a shadowing phenomenon that is a deposition defect. The magnetic plate MP may be any of a permanent magnet and an electromagnet.

The support plate YK may accommodate the magnetic plate MP. The support plate YK may be coupled with the transferring part DM to allow the magnetic plate MP to closely contact the base substrate BS or separate the magnetic plate MP from the base substrate BS.

In an embodiment, the cooling plate (not shown) may be disposed between the base substrate BS and the support plate YK. The cooling plate may cool the base substrate BS or the mask MS to prevent or substantially prevent the base substrate BS or the mask MS from being overheated in the deposition process. Thus, the base substrate BS may be prevented or substantially prevented from being deformed. A cooling line to which a coolant or a cooled air is injected may be provided inside the cooling plate.

The transferring part DM is connected to the pressing part PM. In an embodiment, the transferring part DM may include a transferring rod ML and a transferring main body MC. The transferring main body MC may transfer the pressing part PM by means of the transferring rod ML in the third direction D3, i.e., a vertical direction.

For example, the transferring main body MC may be disposed outside the chamber CH. The transferring main body MC may be realized by any of a cylinder or a motor. For example, when the transferring main body MC is a cylinder, the transferring rod ML may be a piston. For example, when the transferring main body MC is a motor, the transferring rod ML may be a ball screw shaft that is movable in the vertical direction by rotation of the motor. However, the embodiments of the inventive concept are not limited thereto. For example, the transferring part DM may include any of various devices as long as the transferring part DM is able to transfer the pressing part PM.

Referring to FIG. 4, each of the mask MS and the support sticks LS according to an embodiment of the inventive concept may have a magnetic moment (e.g., a predetermined magnetic moment). Thus, when the support plate YK is coupled to the mask MS by the transferring part DM, the mask MS and the support sticks LS receive a magnetic force from the magnetic plate MP by the magnetic plate MP.

In an embodiment of the inventive concept, a magnetic force between the magnetic plate MP and the mask MS may be greater than that between the magnetic plate MP and the support sticks LS.

In an embodiment of the inventive concept, the mask MS may have a magnetic moment of about 120 emu/g, and the support sticks LS may have a magnetic moment of about 10 emu/g or more and about 100 emu/g or less.

If each of the support sticks LS has a magnetic moment less than about 10 emu/g, although the mask MS is attached to the support plate YK, the support sticks LS may not be attached to the mask MS because the support sticks LS have a weak magnetic force, and a deflection phenomenon may occur to generate a shadow defect. In FIG. 4, a comparative support stick LS-X having a magnetic moment less than about 10 emu/g is illustrated by a dotted line.

As the comparative support stick LS-X is deflected by gravity, the mask MS may not be supported by the comparative support stick LS-X to generate a deflection defect. Thus, the shadow defect by which the deposition material is not deposited to a target deposition area may be generated.

If each of the support sticks LS has a magnetic moment greater than about 100 emu/g, since a coupling force between the support sticks LS and the support plate YK is strong, the mask MS disposed between the support sticks LS and the support plate YK may be pushed by the support sticks LS and thus deformed.

In an embodiment of the inventive concept, when the pressing part PM contacts the base substrate BS by the transferring part DM, a tensile force applied to the support sticks LS may be about 0 (zero).

In an embodiment of the inventive concept, each of the support sticks LS may have a thickness of about 20 μm or more to about 200 μm or less in the third direction D3. If each of the support sticks LS has a thickness less than about 20 μm, the support sticks LS may not support a weight of the mask MS, and, thus, the mask MS may be deflected.

If each of the support sticks LS has a thickness greater than about 200 μm, the deposition material may not pass through the mask MS due to the thickness of the support sticks LS, and, thus, a shadow defect by which the deposition material is deposited to the support sticks LS may be generated.

In an embodiment of the inventive concept, as the support sticks LS supporting the mask MS have a certain magnetic moment (e.g., a predetermined magnetic moment), the support sticks LS may be prevented or substantially prevented from being deflected and support the mask MS to prevent or substantially prevent the lifting phenomenon between the base substrate and the mask. Thus, the deposition apparatus EA having improved reliability by preventing or substantially preventing the shadow defect may be provided.

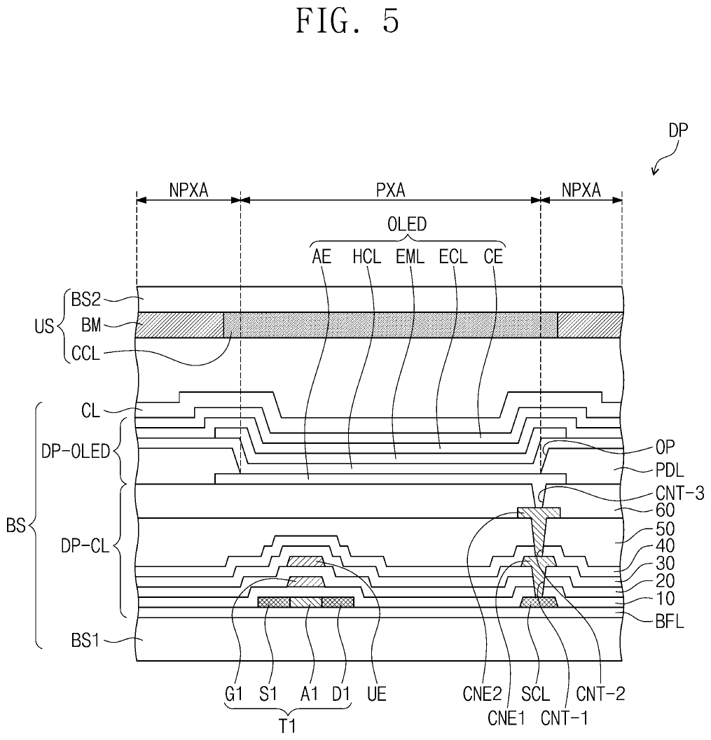

FIG. 5 is a cross-sectional view illustrating a display panel according to an embodiment of the inventive concept. Some of components of a display panel DP in FIG. 5 may be provided through the deposition apparatus EA described in FIGS. 1 to 4. For example, the base substrate BS described in FIGS. 1 to 4 may be a component contained in a base substrate BS of the display panel DP.

A gradation display layer of the display panel DP according to an embodiment may include an organic light emitting layer. Thus, the display panel DP may be an organic light emitting display panel.

In an embodiment, the organic light emitting display panel includes a base substrate BS and an encapsulation substrate US. The base substrate BS includes a first base layer BS1, a circuit device layer DP-CL disposed on the first base layer BS1, a display device layer DP-OLED disposed on the circuit device layer DP-CL, and a cover layer CL disposed on the display device layer DP-OLED. The encapsulation substrate US may include a second base substrate BS2, a black matrix layer BM disposed on the second base substrate BS2, and a color control layer CCL.

The circuit device layer DP-CL may include a plurality of insulation layers, a semiconductor pattern, a conductive pattern, and a signal line. The insulation layer, the semiconductor layer, and the conductive layer may be provided by a method such as coating and deposition. Thereafter, in an embodiment, the insulation layer, the semiconductor layer, and the conductive layer may be selectively patterned by a photolithography method. By using the above-described method, the semiconductor pattern, the conductive pattern, and the signal line, which are contained in the circuit device layer DP-CL and the display device layer DP-OLED, are provided.

In an embodiment, the first base substrate BS1 may include a synthetic resin film. In another embodiment, the first base layer BS1 may include a glass substrate, a metal substrate, or an organic/inorganic composite substrate.

In an embodiment, a buffer layer BFL is disposed on the first base layer BS1. The buffer layer BFL enhances a coupling force between the first base layer BS1 and the semiconductor pattern. In an embodiment, the buffer layer BFL may include any of a silicon oxide layer and a silicon nitride layer. In an embodiment, the silicon oxide layer and the silicon nitride layer may be alternately laminated with each other.

The semiconductor pattern is disposed on the buffer layer BFL. In an embodiment, the semiconductor pattern may include polysilicon. However, embodiments of the inventive concept are not limited thereto. For example, the semiconductor pattern may include amorphous silicon or a metal oxide.

The semiconductor pattern may include a doped area and a non-doped area. The doped area may be doped with a n-type dopant or a p-type dopant. A p-type transistor includes a doped area that is doped with the p-type dopant.

The doped area has a conductivity greater than that of a non-doped area and may serve as an electrode or a signal line. The non-doped area substantially corresponds to an active (or a channel) of the transistor. In other words, one portion of the semiconductor pattern may be the active region of the transistor, another portion may be a source or a drain of the transistor, and another portion may be a connection electrode or a connection signal line.

A transistor T1 is disposed on the buffer layer BFL. A source S1, an active region A1 and a drain D1 of the transistor T1 may be provided from the semiconductor pattern. FIG. 5 illustrates a portion of a connection signal line SCL provided from the semiconductor pattern. Although not separately shown, the connection signal line SCL may be connected to the drain D1 of the transistor T1 on a plane.

A first insulation layer 10 to a sixth insulation layer 60 are disposed on the buffer layer BFL. Each of the first insulation layer 10 to the sixth insulation layer 60 may be an inorganic layer or an organic layer. A gate G1 is disposed on the first insulation layer 10. An upper electrode UE may be disposed on a second insulation layer 20. A first connection electrode CNE1 may be disposed on a third insulation layer 30. The first connection electrode CNE1 may be connected to the connection signal line SCL through a contact hole CNT-1 passing through the first to third insulation layers 10 to 30. A second connection electrode CNE2 may be disposed on a fifth insulation layer 50. The second connection electrode CNE2 may be connected to the first connection electrode CEN1 through a contact hole CNT-2 passing through a fourth insulation layer 40 and the fifth insulation layer 50.

A light emitting device OLED is disposed on the sixth insulation layer 60. A first electrode AE is disposed on the sixth insulation layer 60. The first electrode AE is connected to the second connection electrode CNE2 through a contact hole CNT-3 passing through the sixth insulation layer 60.

The display device layer DP-OLED includes the light emitting device OLED and a pixel defining layer PDL. For example, the pixel defining layer PDL may be an organic layer. The light emitting device OLED includes the first electrode AE, a hole control layer HCL, a light emitting layer EML, an electron control layer ECL, and a second electrode CE.

The pixel defining layer PDL is disposed on the sixth insulation layer 60. An opening OP (herein, referred to as a display opening) is defined in the pixel defining layer PDL. The display opening OP exposes at least a portion of the first electrode AE. In an embodiment of the inventive concept, the pixel defining layer PDL may have a black color. In an embodiment, the pixel defining layer PDL may include a black coloring agent. In an embodiment, the pixel defining layer PDL may include a black dye and a black pigment mixed in a base resin.

FIG. 5 illustrates a light emitting area PXA and a non-light emitting area NPXA disposed adjacent to the light emitting area PXA. In an embodiment, the light emitting area PXA may be defined substantially in correspondence to an area of the first electrode AE exposed by the display opening OP.

In an embodiment, the hole control layer HCL may be disposed on the light emitting area PXA and the non-light emitting area NPXA in common. The hole control layer HCL may include a hole transport layer and further include a hole injection layer. The light emitting layer EML is disposed on the hole control layer HCL. The light emitting layer EML may be disposed on an area corresponding to the display opening OP.

The electron control layer ECL is disposed on the light emitting layer EML. The electron control layer ECL may include an electron transport layer and further include an electron injection layer. The second electrode CE is disposed on the electron control layer ECL.

The cover layer CL is disposed on the second electrode CE. The cover layer CL may include a plurality of thin-films. In an embodiment, the cover layer CL may include a capping layer and a thin-film encapsulation layer.

The second base layer BS2 may be spaced apart from the cover layer CL. In an embodiment, the second base layer BS2 may be any of a glass substrate, a plastic substrate, and a substrate containing polyimide (PI).

The color control layer CCL may transmit first color light or convert the first color light into second color light or third color light according to a color of light. In an embodiment, the color control layer CCL may include a quantum-dot, and the first color light may be blue light.

The black matrix layer BM may overlap the non-light emitting area NPXA. The black matrix layer BM may have a black color. Although the black matrix layer BM may include a material absorbing light, embodiments of the inventive concept are not limited thereto.

The deposition apparatus EA according to an embodiment of the inventive concept may be used to provide the light emitting layer EML containing an organic material among components contained in the light emitting device OLED. However, embodiments of the inventive concept are not limited thereto. For example, a component provided through the deposition process among components provided to the base layers BS1 and BS2 of the display panel DP may be provided by the deposition apparatus EA according to an embodiment of the inventive concept.

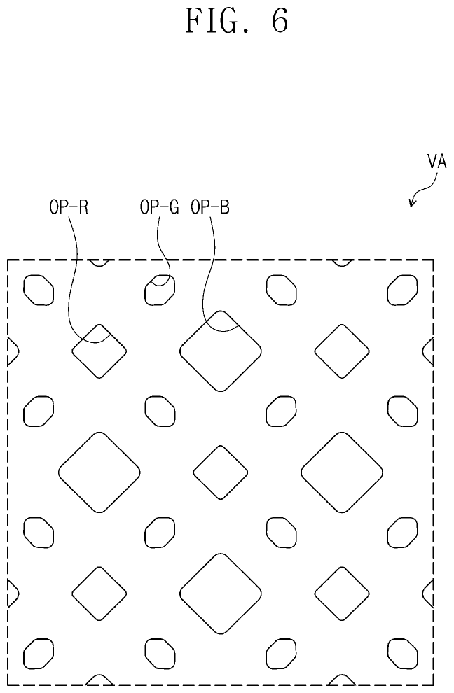

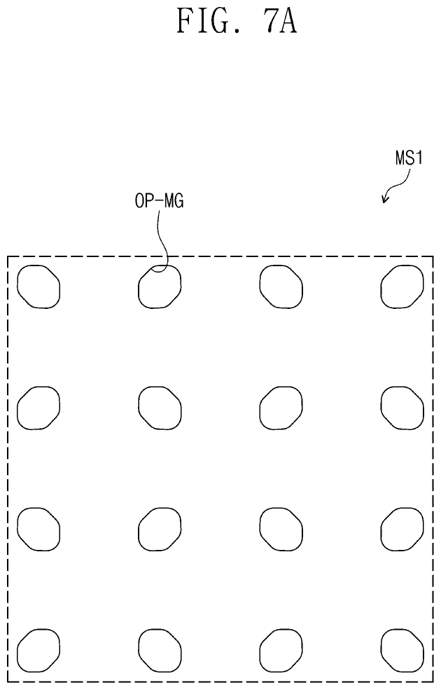

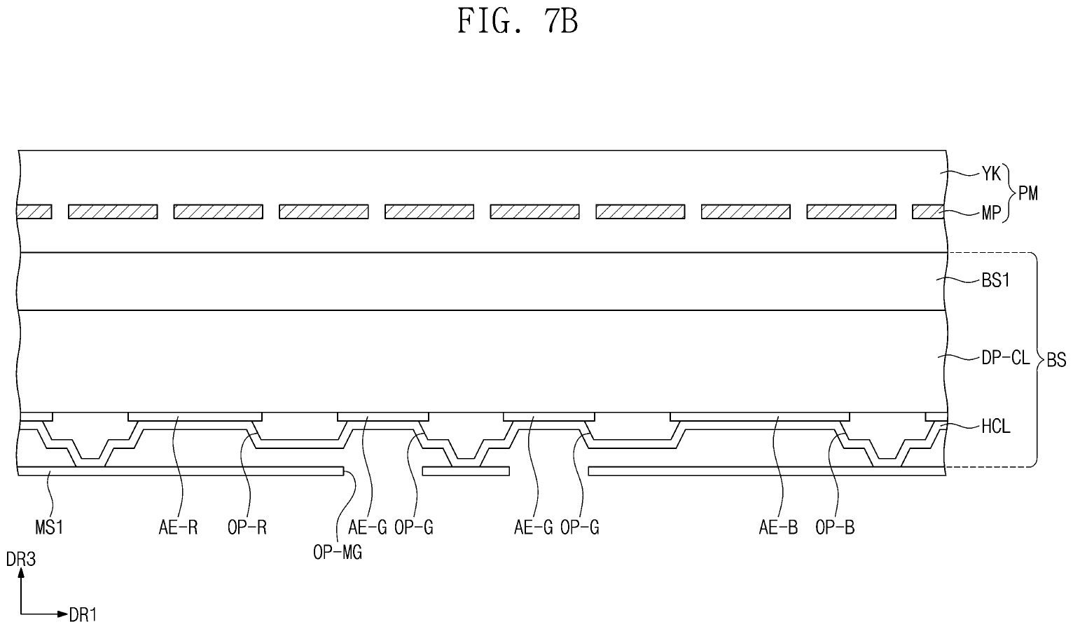

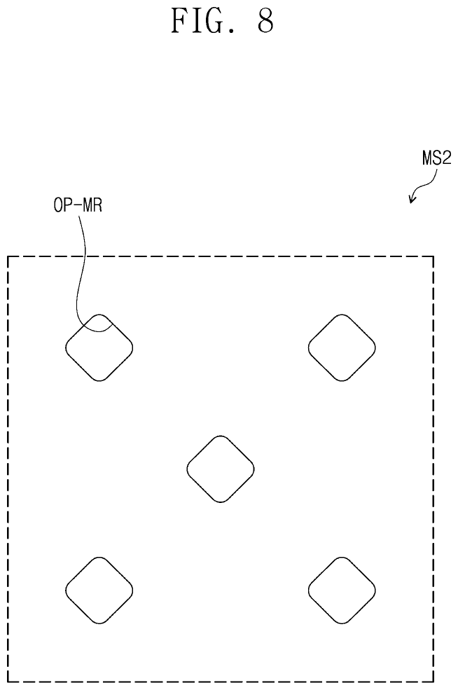

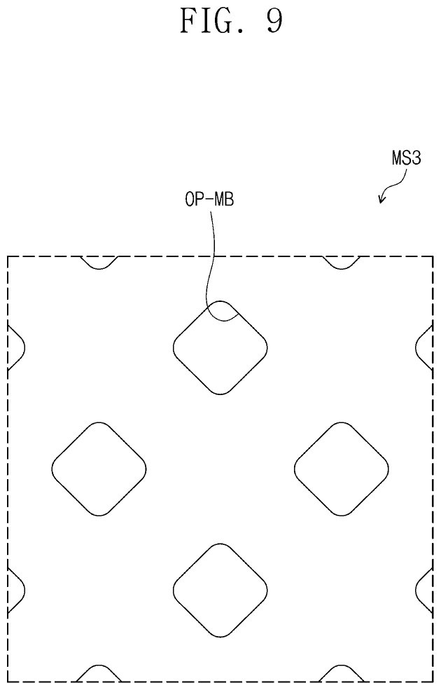

FIG. 6 is an enlarged plan view illustrating a region “VA” of FIG. 2; FIG. 7A is an enlarged plan view illustrating a first mask according to an embodiment of the inventive concept; FIG. 7B is a cross-sectional view illustrating an arrangement relationship between the first mask in FIG. 7A and a unit cell area; FIG. 8 is an enlarged plan view illustrating a second mask according to an embodiment of the inventive concept; and FIG. 9 is an enlarged plan view illustrating a third mask according to an embodiment of the inventive concept.

FIG. 6 illustrates a plan view of the pixel defining layer PDL (refer to FIG. 5) provided to the base substrate BS (refer to FIG. 1). Herein, a method for forming the light emitting layer EML (refer to FIG. 5) in each of display openings OP-R, OP-G, and OP-B defined in the pixel defining layer PDL by using the deposition apparatus EA according to an embodiment of the inventive concept will be described with reference to FIGS. 6 to 9.

As illustrated in FIG. 6, in an embodiment, three kinds of display openings OP-R, OP-G, and OP-B may be formed in the pixel defining layer PDL. The three kinds of display openings OP-R, OP-G, and OP-B may include a first display opening OP-G, a second display opening OP-R, and a third display opening OP-B, which are distinguished according to areas thereof.

Each of the first display opening OP-G, the second display opening OP-R, and the third display opening OP-B may have an area that is proportional to a light emitting area (or an area of the first electrode) of a corresponding pixel. In the embodiment, the first display opening OP-G, the second display opening OP-R, and the third display opening OP-B may correspond to a light emitting device of a green pixel, a light emitting device of a red pixel, and a light emitting device of a blue pixel, respectively.

First to third masks MS1 to MS3 in FIGS. 7A, 8, and 9 may be used to form a light emitting layer of the green light emitting device, a light emitting layer of the red light emitting device, and a light emitting layer of the blue light emitting device in the first display opening OP-G, the second display opening OP-R, and the third display opening OP-B, respectively.

FIG. 7B illustrates an arrangement state of the base substrate BS on the first mask MS1. In an embodiment, the base substrate BS in FIG. 7B may be provided in a state in which the hole control layer HCL is formed in the base substrate BS in FIG. 5. However, a cross-section of the base substrate BS in FIG. 7B is merely provided as an example, and embodiments of the inventive concept are not limited thereto.

The base substrate BS according to an embodiment may include: the pixel defining layer PDL in which the first display opening OP-G, the second display opening OP-R, and the third display opening OP-B are defined; first electrodes AE-G, AE-R, and AE-B having at least a portion exposed by the display openings OP-R, OP-G, and OP-B, respectively; and the hole control layer HCL formed on the pixel defining layer PDL.

The pressing part may be coupled to a surface of the first base layer BS1. The first mask MS1 may closely contact and be coupled to the base substrate BS by the magnetic plate MP of the pressing part PM.

Referring to FIGS. 7A, 8, and 9, the green light emitting layers may be formed on the hole control layer HCL by using the first mask MS1. Thereafter, the red light emitting layers may be formed by using the second mask MS2, and the blue light emitting layers may be formed by using the third mask MS3. Thereafter, the electron control layer ECL in FIG. 5 may be additionally formed.

A first deposition hole OP-MG of the first mask MS1 in FIG. 7A may have an area greater than that of the first display opening OP-G. The mask assembly MSA may be disposed in the chamber CB, and the first display opening OP-G may be disposed inside the first deposition hole OP-MG of the first mask MS1 in a state in which the first mask MS1 is aligned with the base substrate BS.

The second display opening OP-R may be disposed inside the second deposition hole OP-MR of the second mask MS2 in a state in which the second mask MS2 is aligned with the base substrate BS.

The third display opening OP-B may be disposed inside the third deposition hole OP-MB of the third mask MS3 in a state in which the third mask MS3 is aligned with the base substrate BS.

According to embodiments of the inventive concept, as the support sticks supporting the mask have a magnetic moment (e.g., a predetermined magnetic moment), the support sticks may be prevented or substantially prevented from being deflected and support the mask to prevent or substantially prevent a lifting phenomenon between the base substrate and the mask. Thus, the deposition apparatus having improved reliability by preventing or substantially preventing a shadow defect may be provided.

Although some embodiments of the present invention have been described, it is to be understood that the present invention should not be limited to or by these embodiments, but various changes and modifications may be made by one of ordinary skill in the art within the spirit and scope of the present invention as herein claimed.

Hence, the real protective scope of the present invention shall be determined by the technical scope of the accompanying claims.

What is claimed is:

1. A mask assembly comprising:
a frame in which a frame opening is defined;
a plurality of support sticks coupled with the frame to overlap the frame opening, each of the plurality of support sticks extending in a first direction, and the support sticks being arranged in a second direction crossing the first direction; and
a mask on the frame and the support sticks, and extending in the second direction,
wherein the support sticks have a magnetic moment of about 10 emu/g or more and about 100 emu/g or less.

2. The mask assembly of claim 1, wherein the mask has a magnetic moment greater than that of the support sticks.

3. The mask assembly of claim 1, wherein each of the support sticks has a thickness of about 20 μm or more and about 200 μm or less.

4. The mask assembly of claim 1, wherein each of the support sticks comprises stainless steel, and the mask comprises nickel or nickel alloy.

5. The mask assembly of claim 1, wherein the mask comprises a plurality of deposition holes,
a portion of the plurality of deposition holes are covered by the support sticks, and
remaining ones of the plurality of deposition holes are exposed by the support sticks.

6. The mask assembly of claim 1, wherein the frame comprises:
a first extension portion and a second extension portion, which face each other in the first direction; and
a third extension portion and a fourth extension portion, which face each other in the second direction and each connect the first extension portion and the second extension portion.

7. The mask assembly of claim 6, wherein a first end of each of the support sticks is welded to the first extension portion, and a second end of each of the support sticks is welded to the second extension portion, such that the support sticks are coupled to the frame.

8. A deposition apparatus comprising:
a chamber;
a deposition source in the chamber;
a mask assembly above the deposition source and configured to support a base substrate thereon; and
a pressing part comprising a support plate above the base substrate, and a magnetic plate having a magnetic force,
wherein the mask assembly comprises:
a frame in which a frame opening configured to expose at least a portion of the base substrate is defined;
a plurality of support sticks coupled with the frame to overlap the frame opening; and
a mask on the frame and the support sticks and in which a plurality of deposition holes is defined,
wherein the support sticks have a magnetic moment of about 10 emu/g or more and about 100 emu/g or less.

9. The deposition apparatus of claim 8, wherein each of the support sticks has a thickness of about 20 μm or more and about 200 μm or less.

10. The deposition apparatus of claim 8, wherein a magnetic force between the magnetic plate and the mask is greater than that between the magnetic plate and the support sticks.

11. The deposition apparatus of claim 8, wherein the mask has a magnetic moment greater than that of the support sticks.

12. The deposition apparatus of claim 8, wherein each of the support sticks comprises stainless steel, and the mask comprises nickel or nickel alloy.

13. The deposition apparatus of claim 8, wherein the deposition source comprises an organic material and is configured to evaporate the organic material to inject the evaporated organic material to the frame opening.

14. The deposition apparatus of claim 8, further comprising a seating part configured to support the mask assembly.

15. The deposition apparatus of claim 8, further comprising a transferring part comprising:
a transferring rod connected with the pressing part and located in the chamber; and
a transferring main body connected with the transferring rod to control the transferring rod and located outside the chamber.

16. The deposition apparatus of claim 15, wherein a tensile force applied to the support sticks when the pressing part contacts the base substrate by the transferring part is about 0.

17. The deposition apparatus of claim 8, wherein the base substrate comprises:
a base layer;
a circuit device layer on the base layer and comprising a transistor comprising a plurality of electrodes;
a pixel defining layer on the circuit device layer and in which a plurality of display openings are defined;
first electrodes in which at least one portion is exposed by the display openings; and
a hole control layer on the pixel defining layer,
wherein at least a portion of the plurality of deposition holes overlap the display openings.

18. The deposition apparatus of claim 8, wherein a portion of the plurality of deposition holes are covered by the support sticks, and
remaining ones of the plurality of deposition holes are exposed by the support sticks.

19. The deposition apparatus of claim 8, wherein the frame comprises:
a first extension portion and a second extension portion, which face each other in a first direction; and
a third extension portion and a fourth extension portion, which face each other in a second direction crossing the first direction and each connect the first extension portion and the second extension portion.

20. The deposition apparatus of claim 19, wherein a first end of each of the support sticks is welded to the first extension portion, and a second end of each of the support sticks is welded to the second extension portion, such that the support sticks are coupled to the frame.
